(19) United States
(12) Patent Application Publication
(10) Pub. No.: US 2026/0144120 A1
(43) Pub. Date: May 21, 2026

(54) SEMICONDUCTOR PACKAGES HAVING INTERPOSERS

(71) Applicant: Samsung Electronics Co., Ltd., Suwon-si (KR)

(72) Inventor: Hyunjung Song, Suwon-si (KR)

(21) Appl. No.: 19/388,791

(22) Filed: Nov. 13, 2025

(30) Foreign Application Priority Data
Nov. 15, 2024 (KR) 10-2024-0162710

(51) Int. Cl. H01L 23/00

(52) U.S. Cl. CPC H10W 72/20; H10W 72/072; H10W 72/30; H10W 72/851; H10W 72/07202; H10W 72/252; H10W 74/15; H10W 90/724; H10W 90/734

(57) ABSTRACT

A semiconductor package may include an interposer having a plurality of first interposer pads; a plurality of first conductive bumps respectively on the first interposer pads; a molding layer on the interposer to surround the plurality of first conductive bumps and to expose upper surfaces of the plurality of first conductive bumps; a semiconductor chip having a plurality of chip pads, the semiconductor chip on the molding layer such that the plurality of chip pads of the semiconductor chip faces the interposer; and a plurality of second conductive bumps respectively on the plurality of chip pads, the plurality of second conductive bumps having lower surfaces that respectively contact the upper surfaces of the plurality of first conductive bumps. Each of the plurality of first conductive bumps includes a first bump pillar on the first interposer pad and a first bump solder on the first bump pillar.

### CROSS-REFERENCE TO RELATED APPLICATION

This application claims priority under 35 U.S.C. § 119 to Korean Patent Application No. 10-2024-0162710, filed on November 15, 2024, in the Korean Intellectual Property Office (KIPO), the contents of which are herein incorporated by reference in their entirety.

### BACKGROUND

In a 2.5D package structure, when a semiconductor chip is mounted on an interposer, if there is a large difference in height between bumps of the interposer, a slip phenomenon may occur between the bumps of the interposer and bumps of the semiconductor chip. Furthermore, due to the slip phenomenon, misalignment defects may occur between the bumps of the interposer and the bumps of the semiconductor chip, which may cause reliability problems. In particular, if a solder material is used at the outermost joint of the bump, the bumps all become round during a reflow process, making bonding difficult. In addition, since tolerance constraints on the height of the bump increase, resulting in a decrease in yield.

### SUMMARY

Some aspects of the present disclosure provide semiconductor packages including an interposer having a plurality of conductive bumps capable of preventing boding defects.

According to some implementations, a semiconductor package includes an interposer having a plurality of first interposer pads on a first surface of the interposer; a plurality of first conductive bumps respectively on the plurality of first interposer pads; a molding layer provided on the first surface of the interposer, surrounding the plurality of first conductive bumps, and exposing upper surfaces of the plurality of first conductive bumps; a semiconductor chip having a plurality of chip pads on a third surface thereof, the semiconductor chip on the molding layer such that the third surface of the semiconductor chip faces the interposer; and a plurality of second conductive bumps respectively on the plurality of chip pads of the semiconductor chip, each of the plurality of second conductive bumps having a lower surface that contact the upper surface of each of the plurality of first conductive bumps. Each of the plurality of first conductive bumps includes a first bump pillar provided on each of the plurality of first interposer pads and a first bump solder provided on the first bump pillar to be at least partially exposed from the molding layer.

According to some implementations, a semiconductor package includes a package substrate having a mounting region; an interposer mounted on the mounting region of the package substrate, the interposer including a first chip mounting region and a chip second mounting region spaced apart from the first chip mounting region, the interposer including an interposer substrate having a first surface, a plurality of interposer pads disposed on the first surface of the interposer substrate, a plurality of first conductive bumps respectively provided on the plurality of interposer pads, and a molding layer provided on the first surface of the interposer substrate to cover a side portion of each of the plurality of first conductive bumps; a first semiconductor chip mounted on the first chip mounting region of the interposer; and a second semiconductor chip mounted on the second chip mounting region of the interposer. Each of the plurality of first conductive bumps includes a first bump pillar provided on each of the plurality of interposer pads and a first bump solder provided on the first bump pillar to be at least partially exposed from the molding layer. A height of each of the plurality of first conductive bumps from the interposer is equal to a height of the molding layer from the interposer.

According to some implementations, a semiconductor package includes a package substrate having a mounting region; a semiconductor chip mounted on the mounting region of the package substrate; and an interposer interposed between the package substrate and the semiconductor chip to electrically connect the package substrate to the semiconductor chip. The interposer includes an interposer substrate having a first surface facing the package substrate and a second surface opposite to the firs surface and facing the semiconductor chip; a plurality of interposer pads disposed on the second surface of the interposer substrate; a plurality of conductive bumps respectively provided on the plurality of interposer pads; and a molding layer provided on the second surface of the interposer substrate to at least partially expose the plurality of conductive bumps. Each of the plurality of conductive bumps includes a bump pillar provided each of the plurality of interposer pads and a bump solder provided on the bump pillar to be at least partially exposed from the molding layer. A height of each of the plurality of conductive bumps from the interposer is equal to a height of the molding layer from the interposer.

According to some implementations, a semiconductor package may include an interposer and a semiconductor chip mounted on the interposer. The interposer may include an interposer substrate, a plurality of first interposer pads provided on a surface of the interposer substrate, a plurality of first conductive bumps respectively on the plurality of first interpose pads, and a molding layer provided on the surface of the interposer substrate to at least partially expose the plurality of first conductive bumps. The semiconductor chip may include a semiconductor substrate, a plurality of chip pads provided on a surface of the semiconductor substrate, and a plurality of second conductive bumps respectively provided on the plurality of chip pads.

Each of the plurality of first conductive bumps may include a first bump pillar provided on the first interposer pad and a first bump solder provided on the first bump pillar to be at least partially exposed from the molding layer. Additionally, a height of each of the plurality of first conductive bumps may be equal to a height of the molding layer.

Accordingly, based on the configuration of the first conductive bumps (e.g., since the exposed surfaces of the first conductive bumps are coplanar with each other (or positioned on the same plane)), areas of bonding surfaces of the first conductive bumps may be increased. In addition, in some implementations, as the first conductive bumps have same heights, tolerance for the heights can be reduced, and furthermore, a slip phenomenon may be reduced or prevented. Accordingly, the first conductive bumps may prevent misalignment defects, thereby improving reliability and yield rates.

### BRIEF DESCRIPTION OF THE DRAWINGS

FIG. 1 is a cross-sectional view illustrating an example of a semiconductor package.

FIG. 2 is an enlarged cross-sectional view illustrating portion ‘M1’ in FIG. 1.

FIG. 3 is a plan view illustrating the semiconductor package in FIG. 1.

FIGS. 4 to 26 are views illustrating an example of a method of manufacturing a semiconductor package.

FIG. 27 is a cross-sectional view illustrating an example of a semiconductor package.

FIG. 28 is an enlarged cross-sectional view illustrating portion ‘M5’ in FIG. 27.

FIG. 29 is an enlarged cross-sectional view illustrating portion ‘M6’ in FIG. 27.

FIG. 30 is a plan view illustrating the semiconductor package in FIG. 27.

FIG. 31 is a cross-sectional view illustrating an example of a semiconductor package.

FIG. 32 is an enlarged cross-sectional view illustrating portion ‘M7’ in FIG. 31.

FIG. 33 is an enlarged cross-sectional view illustrating portion ‘M8’ in FIG. 31.

### DETAILED DESCRIPTION

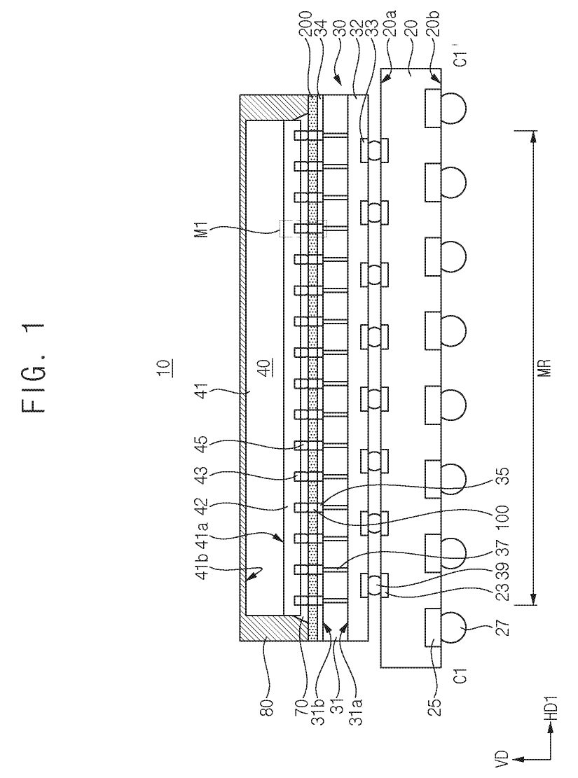

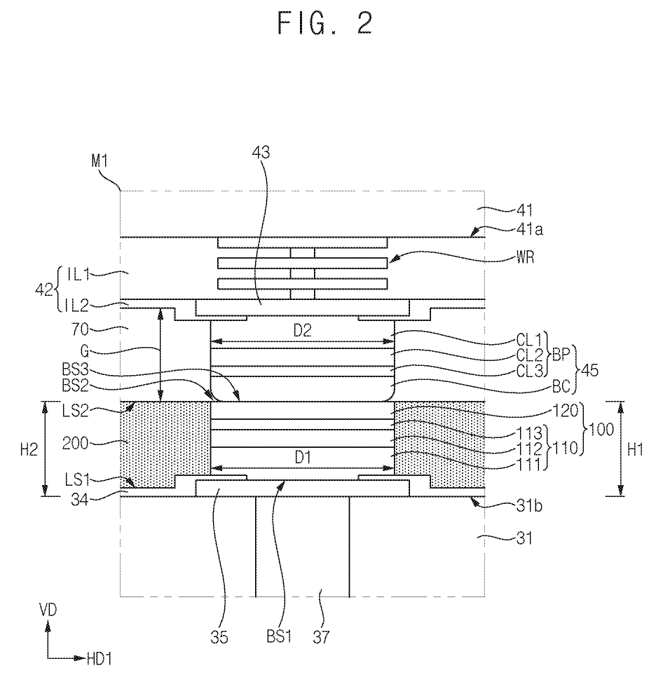

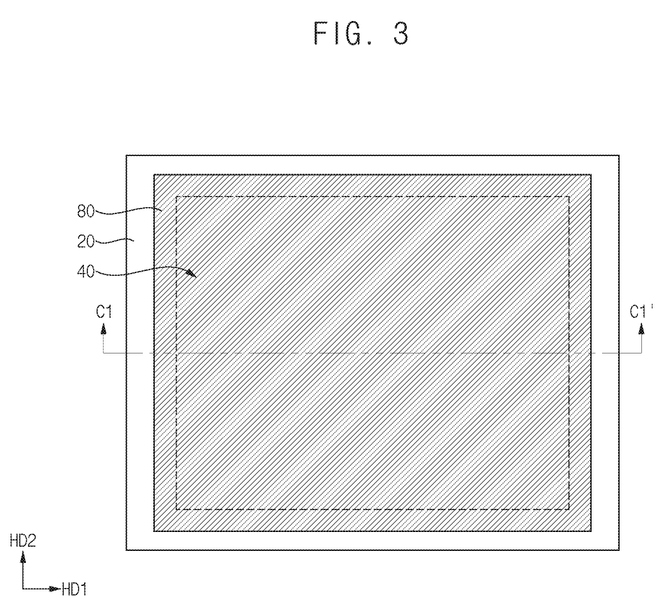

FIG. 1 is a cross-sectional view illustrating an example of a semiconductor package. FIG. 2 is an enlarged cross-sectional view illustrating portion ‘M1’ in FIG. 1. FIG. 3 is a plan view illustrating the semiconductor package in FIG. 1. FIG. 1 is a cross-sectional view taken along the line C1-C1’ in FIG. 3.

Referring to FIGS. 1 to 3, a semiconductor package 10 may include a package substrate 20, an interposer 30 stacked on a mounting region MR of the package substrate 20, a semiconductor chip 40 stacked on the interposer 30, an underfill member 70 filling a gap G between the interposer 30 and the semiconductor chip 40, and a molding member 80 provided on the interposer 30 to cover the semiconductor chip 40. Additionally, the semiconductor package 10 may further include a plurality of external connection members 27 provided on a lower portion of the package substrate 20 and a plurality of conductive connection members 39 provided between the package substrate 20 and the interposer 30. Further, the semiconductor package 10 may include a plurality of first conductive bumps 100 that are provided on an upper side of the interposer 30 to electrically connect the interposer 30 and the semiconductor chip 40, and a plurality of second conductive bumps 45 that are provided on a lower side of the semiconductor chip 40 to electrically connect the interposer 30 and the semiconductor chip 40.

For example, the semiconductor package may be a 2.5D package that includes an interposer disposed between the package substrate and the semiconductor chip to electrically connect the package substrate and the semiconductor chip. The interposer may be a structure for facilitating transmission of electrical signals between the package substrate and the semiconductor chip. It will be appreciated, however, that implementations are not limited thereto. Accordingly, the configuration, arrangement, etc. of the semiconductor package may be varied.

In some implementations, the package substrate 20 may have a first surface 20a and a second surface 20b opposite to the first surface 20a. The package substrate 20 may include a plurality of first substrate pads 23 provided on the first surface 20a and a plurality of second substrate pads 25 provided on the second surface 20b. The package substrate 20 may further include a plurality of external connection members 27 respectively disposed on the plurality of second substrate pads 25. For example, the plurality of external connection members may be structures configured to connect the semiconductor package to an external device on which the package substrate is mounted.

The package substrate 20 may include the mounting region MR in a central portion of the package substrate. The plurality of first substrate pads 23 may be provided within the mounting region MR such that the plurality of first substrate pads 23 are at least partially exposed from the first surface 20a. For example, the mounting region may be a region in which the semiconductor chip is mounted as will be described later.

While examples of pads are illustrated in the figures, it will be appreciated that implementations are not limited thereto. Accordingly, the number, size, arrangement, shape, etc. of the pads may be varied. Additionally, the package substrate may have internal wirings that electrically connect the pads.

In some implementations, the interposer 30 may includes an interposer substrate 31 having a first surface 31a and a second surface 31b opposite to the first surface 31a, a first interposer insulation layer 32 provided on the first surface 31a of the interposer substrate 31, and a plurality of first interposer pads 33 provided in the first interposer insulation layer 32 to be at least partially exposed from the first interposer insulation layer 32, a second interposer insulation layer 34 provided on the second surface 31b of the interposer substrate 31, and a plurality of second interposer pads 35 provided in the second interposer insulation layer 34 to be at least partially exposed from the second interposer insulation layer 34. The interposer 30 may further include a plurality of through vias 37 that are disposed within the interposer substrate 31 to electrically connect the plurality of first interposer pads 33 and the plurality of second interposer pads 35, and a plurality of conductive connection members 39 disposed on the plurality of first interposer pads 33 respectively.

The plurality of first interposer pads 33, the plurality of second interposer pads 35, the plurality of through vias 37, and the plurality of conductive connection members 39 may include a conductive metallic material.

Although examples of pads and through vias are illustrated in the figures, it will be appreciated that implementations are not limited thereto. Accordingly, the number, size, arrangement, shape, etc. of the pads and through vias may be varied.

The interposer 30 may be mounted on the mounting region MR of the package substrate 20. For example, the interposer 30 may be mounted on the package substrate 20 via the plurality of conductive connection members 39 respectively provided between the plurality of first interposer pads 33 and the plurality of first substrate pads 23 for electrical connection with the package substrate 20.

The interposer 30 may include the plurality of first conductive bumps 100 that are respectively provided on the plurality of second interposer pads 35, and a molding layer 200 provided on the second interposer insulation layer 34 to at least partially expose the plurality of first conductive bumps 100.

While examples of the first conductive bumps 100 are illustrated in the figures, it will be appreciated that implementations are not limited thereto. Accordingly, the number, size, placement, shape, etc. of the conductive bumps may be varied.

As shown in FIG. 2, in some implementations, each of the plurality of first conductive bumps 100 may include a first bump pillar 110 and a first bump solder 120 sequentially stacked on each of the plurality of second interposer pads 35 to be electrically connected to each other.

The first bump pillar 110 may include a plurality of conductive layers stacked sequentially on the second interposer pad to be electrically connected to each other. For example, the first bump pillar may include a first conductive layer 111, a second conductive layer 112, and a third conductive layer 113 stacked sequentially on the second interposer pad.

However, implementations are not limited thereto. Accordingly, the number, size, arrangement, shape, etc. of the conductive layers may be varied.

The first bump pillar 110 and the first bump solder 120 may include a conductive metallic material. For example, the first bump pillar 110 may include copper (Cu), nickel (Ni), etc, and the first bump solder 120 may include a solder material such as tin (Sn). For example, if the first conductive bump 100 has a CNCS (Cu-Ni-Cu-Sn) structure, the first conductive layer 111 and the third conductive layer 113 may include copper (Cu), the second conductive layer 112 may include nickel (Ni), and the first bump solder 120 may include tin (Sn). However, it will be appreciated that implementations are not limited thereto, and accordingly, the materials of the first bump pillar 110 and the first bump solder 120 may be changed.

In some implementations, the molding layer 200 may cover a side portion (or side surface) of each of the plurality of first conductive bumps 100 and the molding layer 200 may cover the second interposer insulation layer 34. For example, the molding layer 200 may include a thermosetting material that hardens when heat is applied. The molding layer 200 may include epoxy molding compounds (EMC). For example, the molding layer 200 may be a structure for physically protecting the plurality of first conductive bumps 100.

The molding layer 200 may have a first surface LS1 and a second surface LS2 opposite to the first surface LS1. The first surface LS1 may be a surface in contact with the second interposer insulation layer 34, and the second surface LS2 may be a surface facing the semiconductor chip 40.

The molding layer 200 may at least partially expose a surface of each of the plurality of first conductive bumps 100. For example, each of the plurality of first conductive bumps 100 may have a first surface BS1 and a second surface BS2 opposite to (or spaced apart from) the first surface BS1 in a vertical direction VD. The first surface BS1 may be a surface in contact with each of the plurality of second interposer pads 35, and the second surface BS1 may be a side facing the semiconductor chip to be described later. The second surface BS1 of each of the plurality of first conductive bumps 100 may be exposed from the second surface LS2 of the molding layer 200.

A height of the molding layer 200 may be the same as a height of each of the plurality of first conductive bumps 100. Each of the plurality of first conductive bumps 100 may have a first height H1, and the molding layer 200 may have a second height H2 equal to the first height H1. For example, the first height may be a distance in a vertical direction VD from the second surface 31b of the interposer substrate 31 to the second surface BS2 of each of the plurality of first conductive bumps 100. The second height may be a distance in the vertical direction VD from the second surface 31b of the interposer substrate 31 to the second surface LS2 of the molding layer 200.

For example, the second surface BS2 of each of the plurality of first conductive bumps 100 and the second surface LS2 of the molding layer 200 may be in the same plane.

In some implementations, the semiconductor chip 40 may include a semiconductor substrate 41 having a first surface 41a and a second surface 41b opposite to the first surfaced 41a, a semiconductor insulation layer 42 provided on the semiconductor substrate 41, and a plurality of chip pads 43 provided in the semiconductor insulation layer 42 to be at least partially exposed from the semiconductor insulation layer 42. In addition, the semiconductor chip 40 may further include a plurality of second conductive bumps 45 respectively provided on the plurality of chip pads 43 to be in contact with the interposer 30. For example, the first surface of the semiconductor substrate 41 may be an active surface on which a circuit is formed, and the second surface 41b of the semiconductor substrate 41 may be an inactive surface. The plurality of chip pads 43 and the plurality of second conductive bumps 45 may include a conductive metallic material for electrical connection.

Although examples of pads and conductive bumps are illustrated in the figures, it will be appreciated that implementations are not limited thereto. Accordingly, the number, size, arrangement, shape, etc. of the pads and conductive bumps may be varied.

The semiconductor insulation layer 42 may be provided on the first surface 41a as the active surface of the semiconductor substrate 41. The semiconductor insulation layer 42 may include a plurality of insulation layers IL1 and IL2 and a plurality of wirings WR in the insulation layers. Additionally, the plurality of chip pads 43 may be provided in the outermost insulation layer IL2 of the semiconductor insulation layer 42.

The semiconductor chip 40 may be mounted on the interposer 30 via the plurality of second conductive bumps 45 that are respectively provided between the plurality of chip pads 43 and the plurality of first conductive bumps 100 to form a gap G between the semiconductor chip 40 and the interposer 30. For example, the plurality of second conductive bumps 45 of the semiconductor chip 40 may respectively contact the plurality of first conductive bumps 100, to electrically connect the interposer 30 and the semiconductor chip 40. For example, a lower surface BS3 of each of the plurality of second conductive bumps 45 may be in contact with the upper surface BS2 of each of the plurality of first conductive bumps 100.

A diameter of each of the plurality of second conductive bumps 45 may be the same as or smaller than a diameter of each of the plurality of first conductive bumps 100. For example, each of the plurality of first conductive bumps 100 may have a first diameter D1 in a horizontal direction and each of the plurality of second conductive bumps 45 may have a second diameter D2 in the horizontal direction that is equal to or smaller than the first diameter D1.

In some implementations, each of the plurality of second conductive bumps 45 may include a second bump pillar BP and a second bump solder BC sequentially stacked on each of the plurality of chip pads 43 to be electrically connected to each other.

The second bump pillar BP may include a plurality of conductive layers stacked sequentially on the chip pad to be electrically connected to each other. For example, the second bump pillar may include a fourth conductive layer CL1, a fifth conductive layer CL2, and a sixth conductive layer CL3 stacked sequentially on the chip pad.

Although examples of conductive layers are illustrated in the figures, it will be appreciated that implementations are not limited thereto. Accordingly, the number, size, arrangement, shape, etc. of the conductive layers may be varied.

The second bump pillar BP and the second bump solder BC may include a conductive metallic material. For example, the second bump pillar BP may include copper (Cu), nickel (Ni), etc, and the second bump solder BC may include a solder material such as tin (Sn). For example, if the second conductive bump has a CNCS (Cu-Ni-Cu-Sn) structure, the fourth conductive layer CL1 and the sixth conductive layer CL3 may include copper (Cu), the fifth conductive layer CL2 may include nickel (Ni), and the second bump solder BC may include tin (Sn). However, it will be appreciated that implementations are not limited thereto, and accordingly, the materials of the second bump pillar and the second bump solder may be changed.

The first diameter D1 of the plurality of first conductive bumps 100 may be constant along the vertical direction VD. The second diameter D2 of the plurality of second conductive bumps 45 may vary along the vertical direction VD. The second diameter D2 of the plurality of second conductive bumps 45 may gradually decrease towards the plurality of first conductive bumps 100 along the vertical direction VD. For example, the second bump solder BC of each of the plurality of second conductive bumps 45 may have a rounded shape.

In some implementations, the underfill member 70 may at least partially fill the gap G between the interposer 30 and the semiconductor chip 40 to cover the plurality of second conductive bumps 45 of the semiconductor chip 40. For example, the underfill member may be a structure for physically protecting the plurality of second conductive bumps 45.

In some implementations, the molding member 80 may be provided on the interposer 30 to cover the semiconductor chip 40. For example, the molding member 80 may be a structure for physically protecting the semiconductor chip 40.

As mentioned above, the semiconductor package 10 may include the package substrate 20, the interposer 30 stacked on the package substrate 20, the semiconductor chip 40 stacked on the interposer 30, the underfill member 70 provided between the interposer 30 and the semiconductor chip 40, and the molding member 80 covering the semiconductor chip 40.

The interposer may include the interposer substrate 31, the plurality of first interposer pads 33 provided on the first surface of the interposer substrate 31, the plurality of first conductive bumps 100 respectively provided on the plurality of first interposer pads 33, and the molding layer 200 provided on the second surface 31b of the interposer substrate 31 to cover the side portion of each of the plurality of first conductive bumps 100. The semiconductor chip may include the semiconductor substrate 41, the plurality of chip pads 43 provided on the first surface 41a of the semiconductor substrate 41, and the plurality of second conductive bumps 45 provided on the plurality of chip pads 43 respectively.

Each of the plurality of first conductive bumps 100 may include the first bump pillar 110 provided on the first interposer pad and the first bump solder 120 provided on the first bump pillar 110 to be at least partially exposed from the molding layer 200. The height H1 of each of the plurality of first conductive bumps 100 may be the same as the height H2 of the molding layer 200.

The exposed surface BS2 of each of the first conductive bumps 100 and the upper surface LS2 of the molding layer 200 may be coplanar with each other, thereby increasing the bonding surface of each of the first conductive bumps. Further, since the first conductive bumps 100 have the same heights, slip phenomena can be prevented, and furthermore, the tolerance for the heights may be reduced. Thus, the first conductive bumps 100 may prevent misalignment, thereby increasing reliability and the yield rate.

Hereinafter, an example of a method of manufacturing the semiconductor package 10 in FIG. 1 will be described.

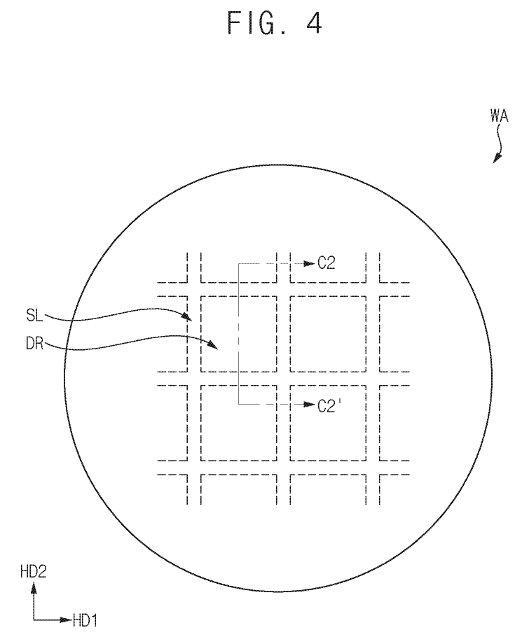

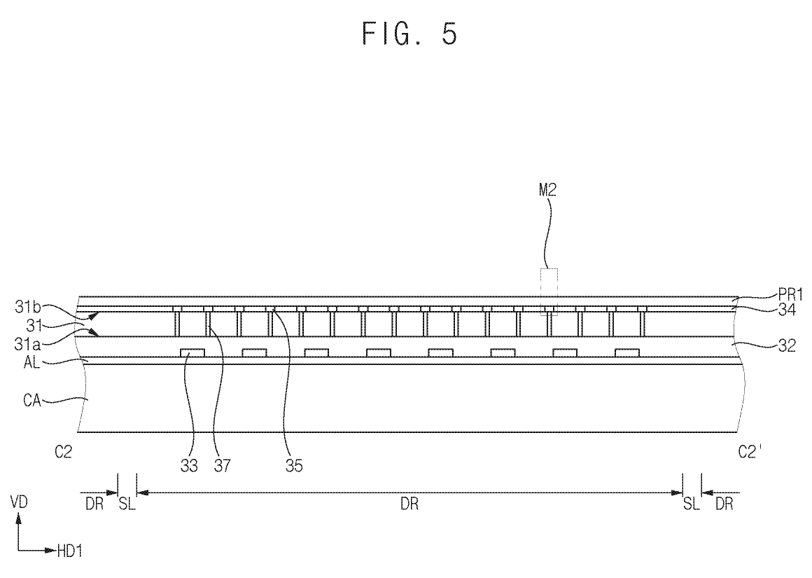

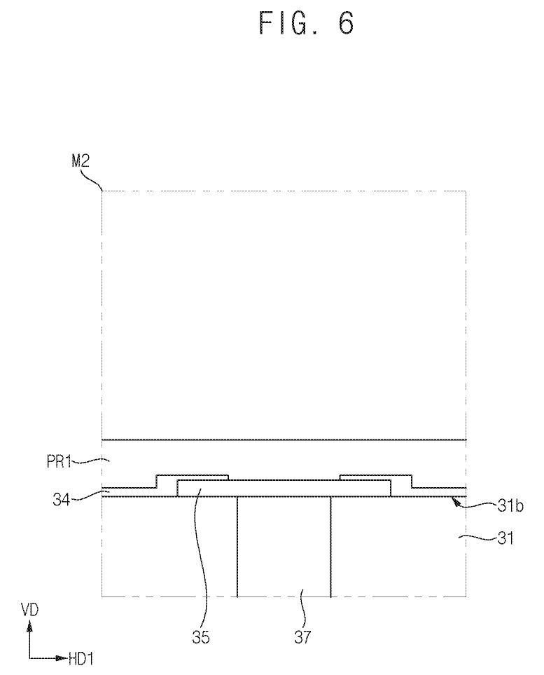

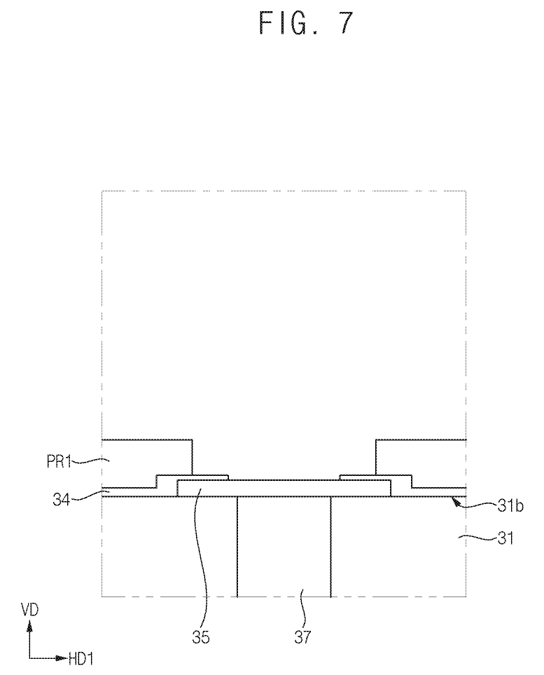

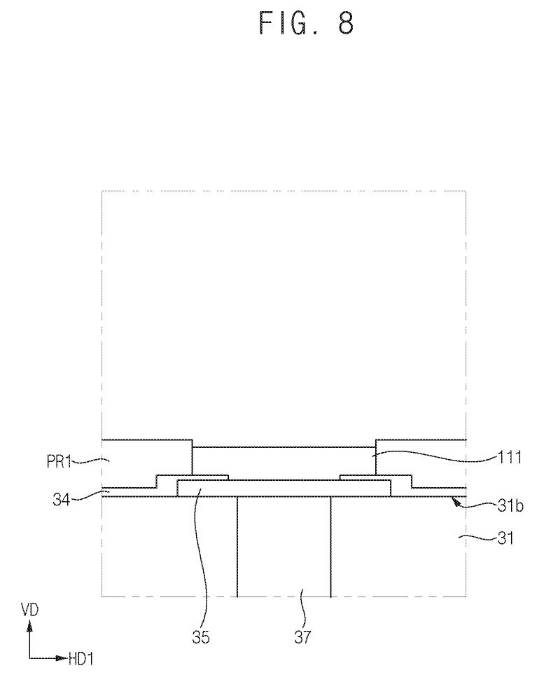

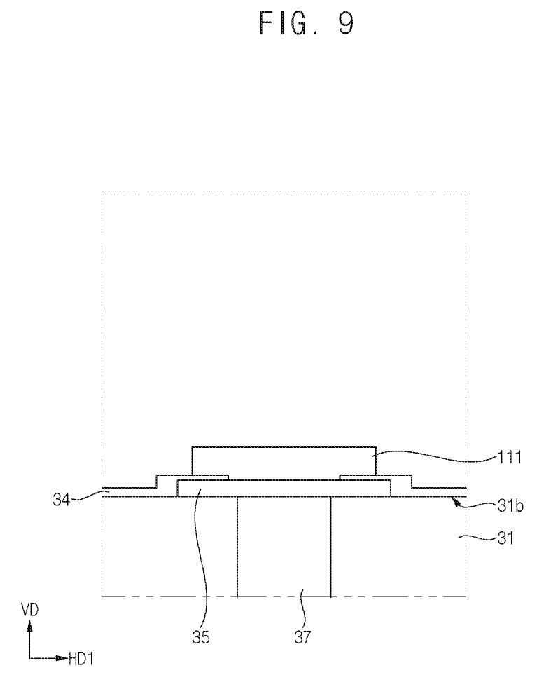

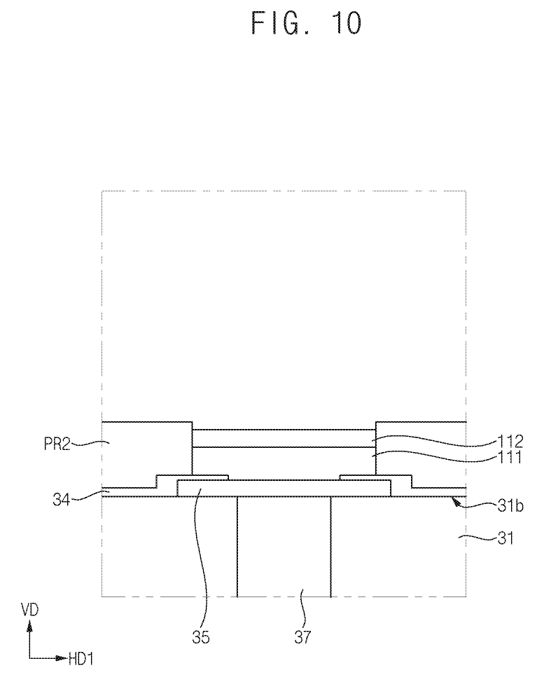

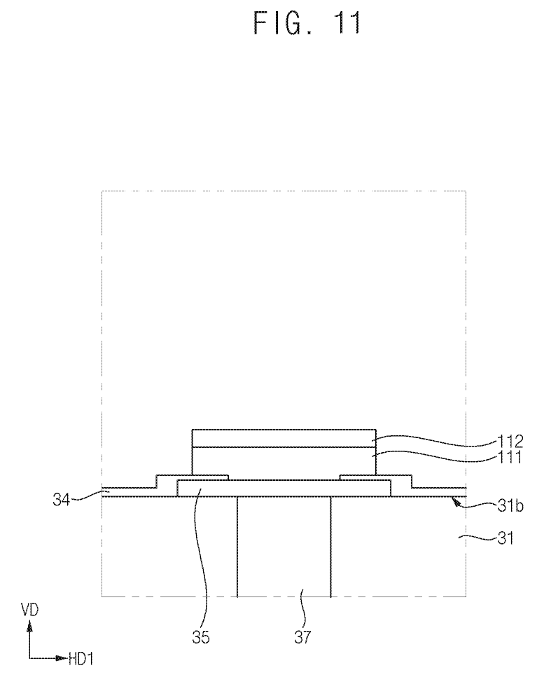

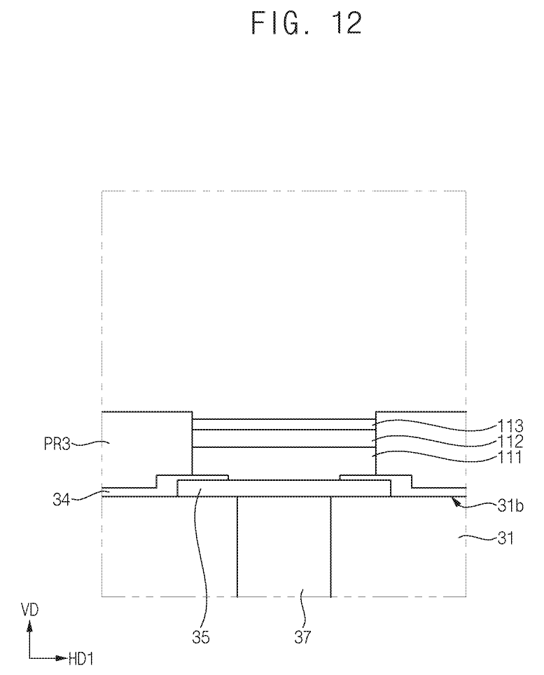

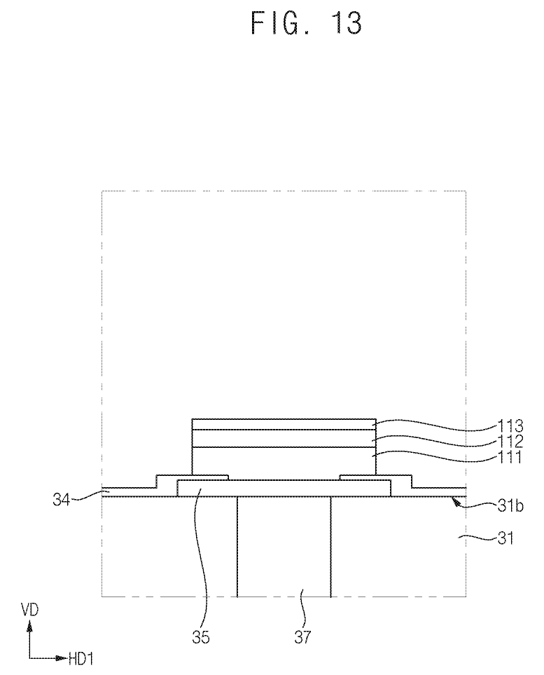

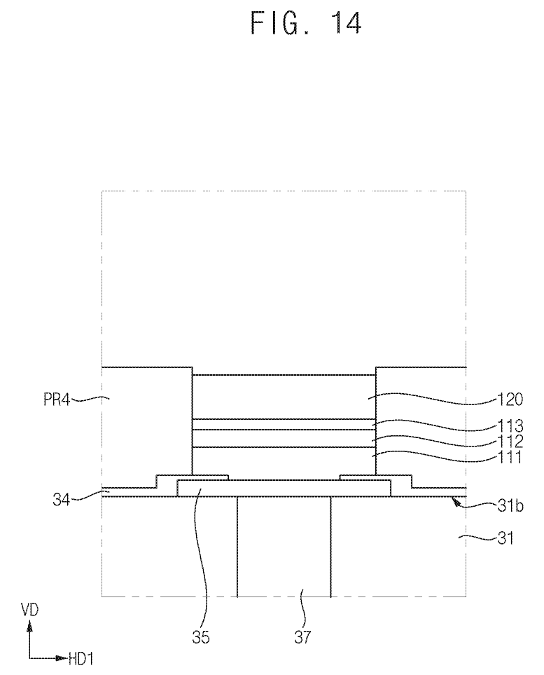

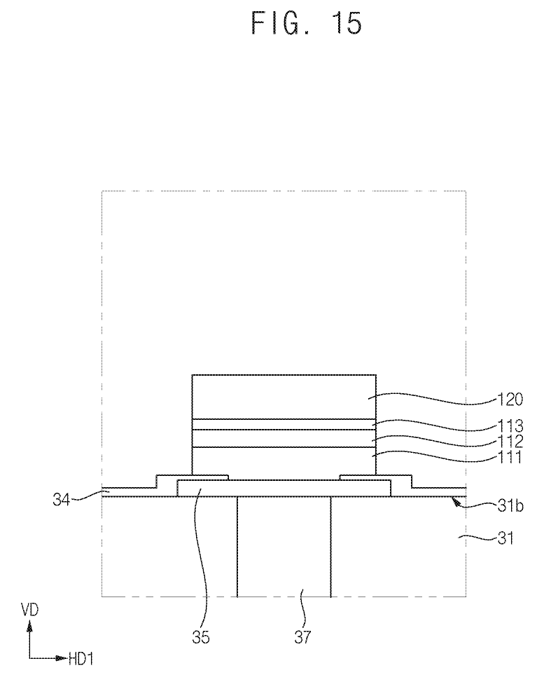

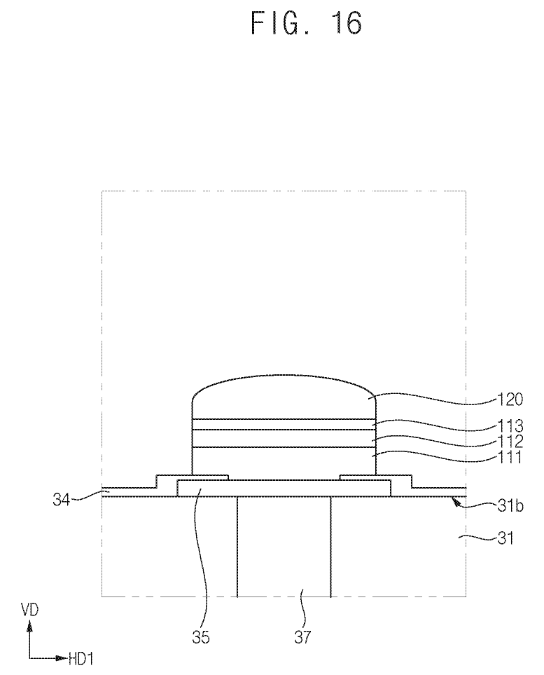

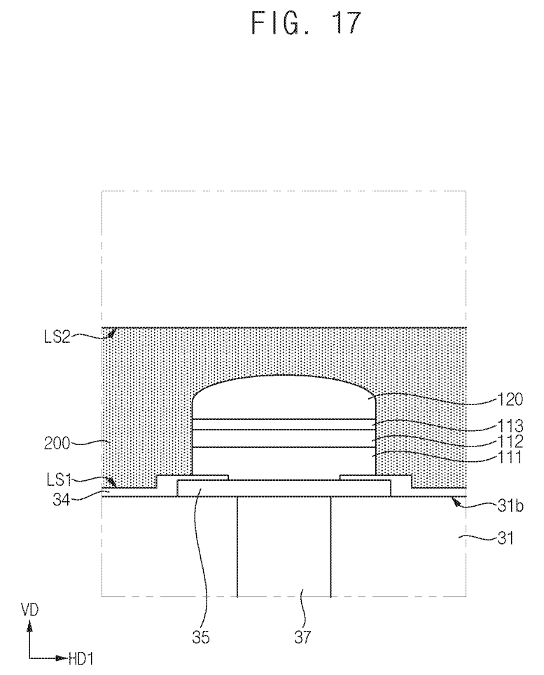

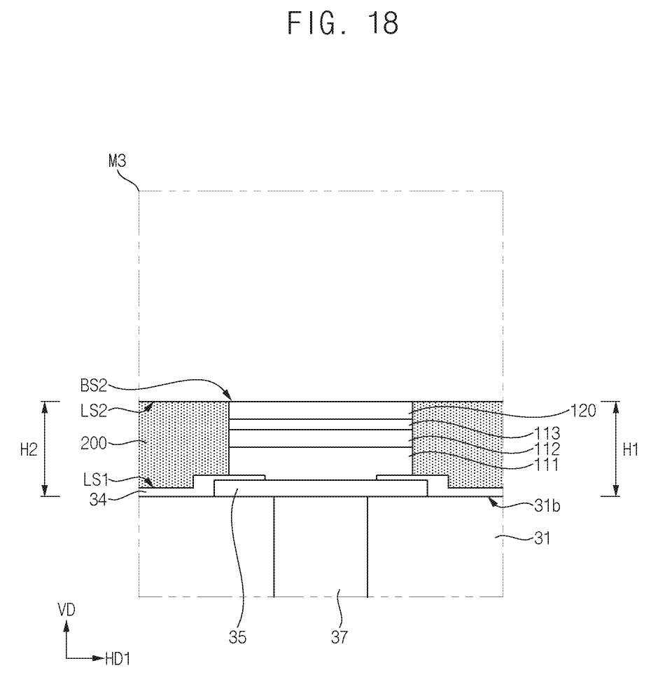

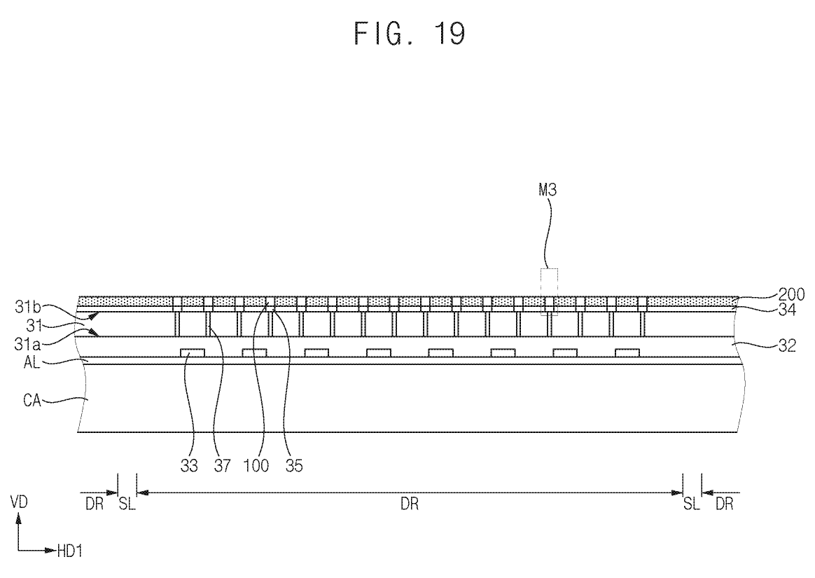

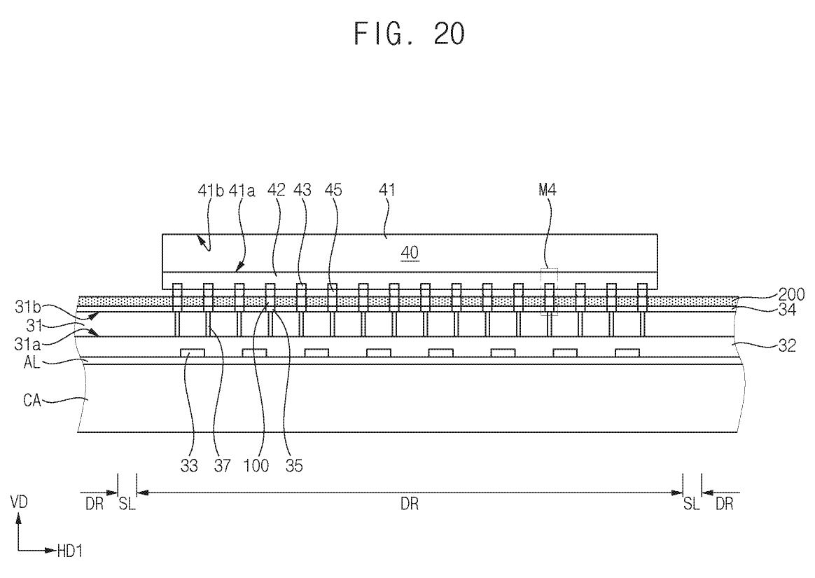

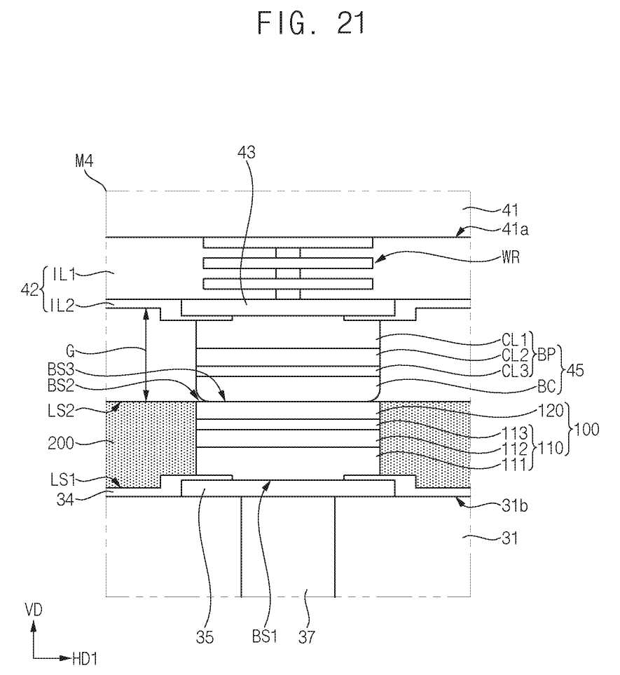

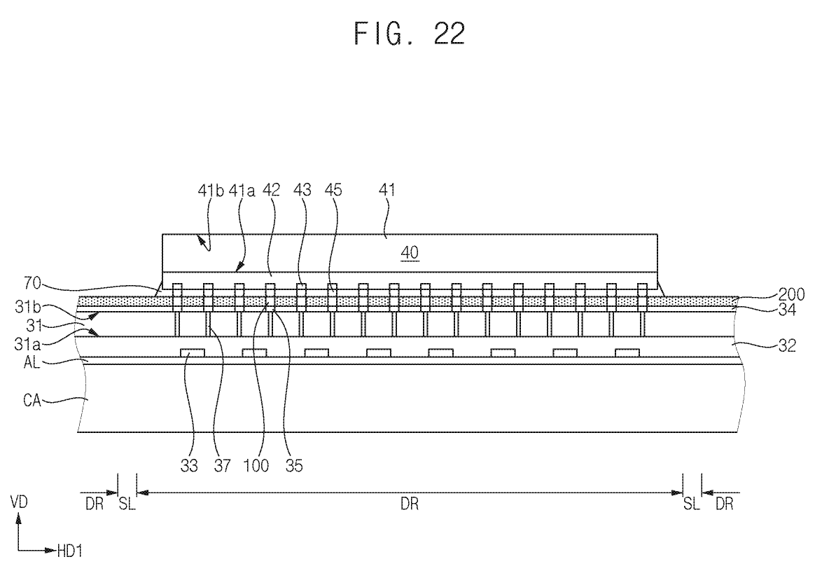

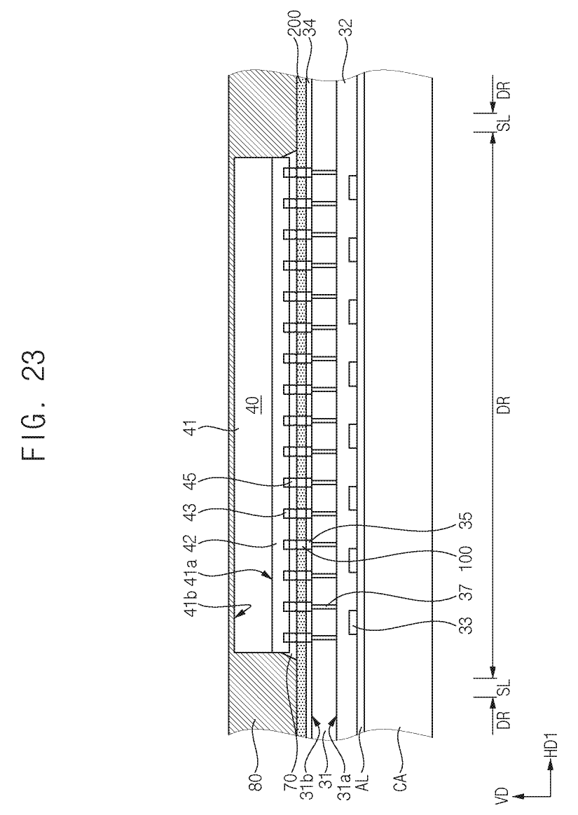

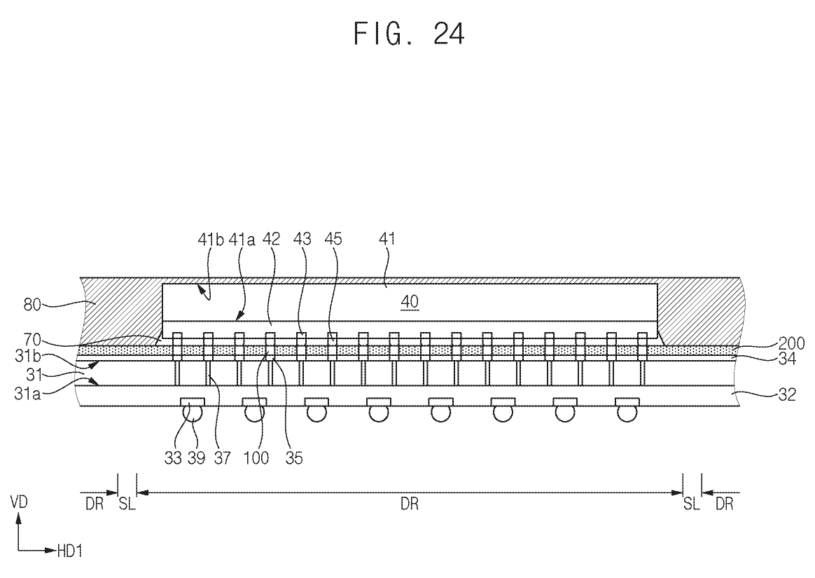

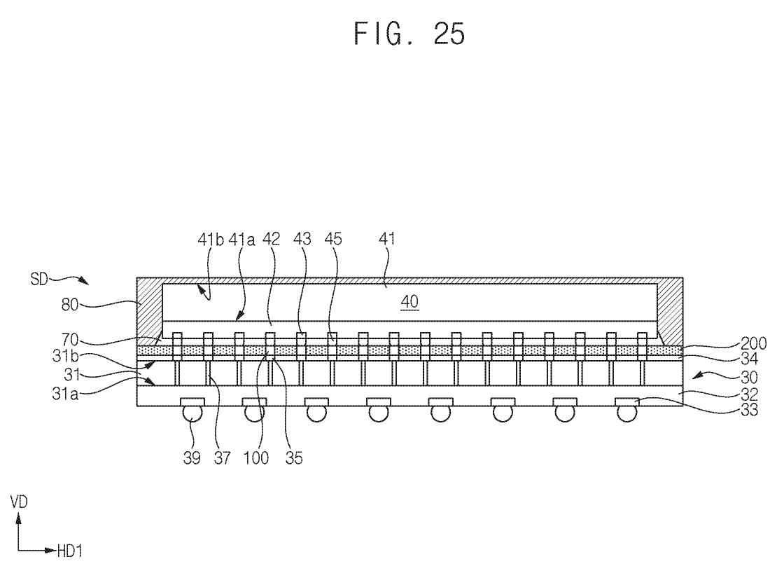

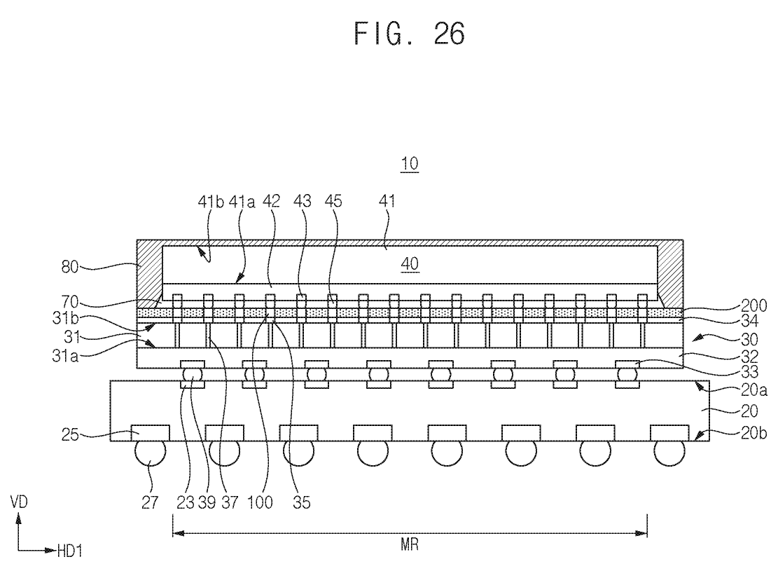

FIG. 4 is a plan view illustrating a wafer in accordance with example embodiments. FIG. 5 is a cross-sectional view taken along the line C2-C2’ in FIG. 4. FIG. 6 is an enlarged cross-sectional view illustrating portion ‘M2’ in FIG. 5. FIGS. 7 to 9 are views illustrating a process of forming a first conductive layer on an interposer pad in FIG. 6. FIGS. 10 and 11 are views illustrating a process of forming a second conductive layer on the first conductive layer in FIG. 9. FIGS. 12 and 13 are views illustrating a process of forming a third conductive layer on the second conductive layer in FIG. 11. FIGS. 14 to 16 are views illustrating a process of forming a first conductive bump by forming and heating a bump solder on the third conductive layer in FIG. 13. FIGS. 17 to 19 are views illustrating a process of forming a molding layer at least partially exposing the first conductive bump in FIG. 16. FIG. 18 is an enlarged cross-sectional view illustrating portion ‘M3’ in FIG. 19. FIGS. 20 and 21 are views illustrating a process of mounting a semiconductor chip on the interposer in FIG. 19. FIG. 21 is an enlarged cross-sectional view illustrating portion ‘M4’ in FIG. 20. FIG. 22 is a cross-sectional view illustrating a process of providing an underfill member between the interposer and the semiconductor chip in FIG. 21. FIG. 23 is a cross-sectional view illustrating a process of forming a molding member covering the semiconductor chip on the interposer in FIG. 22. FIG. 24 is a cross-sectional view illustrating a process of attaching conductive connection members below the interposer in FIG. 23. FIG. 25 is a cross-sectional view illustrating a process of forming an individualized semiconductor device by cutting the interposer and the molding member in FIG. 24. FIG. 26 is a cross-sectional view illustrating a process of completing a semiconductor package by mounting the individualized semiconductor device in FIG. 25 on a package substrate.

Since the semiconductor package manufactured by the manufacturing processes illustrated in FIGS. 4 to 26 is substantially similar to or the same as the semiconductor package described with reference to FIGS. 1 to 3, identical or similar components are denoted by the same reference numerals, and repeated descriptions of identical or similar components are omitted.

Referring to FIGS. 4 to 9, a wafer WA having a plurality of die regions DR and a scribe lane region SL surrounding the plurality of die regions DR and including a plurality of second interposer pads 35 in each of the plurality of die regions DR may be provided, and a first conductive layer 111 may be formed on each of the second interposer pads 35. For example, the first conductive layer may include a metallic material such as copper (Cu), nickel (Ni), etc.

In some implementations, the wafer WA may include an interposer substrate 31 having a first surface 31a and a second surface 31b opposite to the first surface 31a, a first interposer insulation layer 32 provided on the first surface 31a of the interposer substrate 31, and a plurality of first interposer pads 33 provided in the first interposer insulation layer 32 to be at least partially exposed from the first interposer insulation layer 32, a second interposer insulation layer 34 provided on the second surface 31b of the interposer substrate 31, and a plurality of second interposer pads 35 provided in the second interposer insulation layer 34 to be at least partially exposed from the second interposer insulation layer 34. The interposer 30 may further include a plurality of through vias 37 disposed within the interposer substrate 31 to electrically connect the plurality of first interposer pads 33 and the plurality of second interposer pads 35.

For example, the wafer WA may be attached to a carrier CA by an adhesive layer AL that covers the first interposer insulation layer 32 of the wafer WA.

Then, a first photoresist layer PR1 may be formed on the second interposer insulation layer 34 of the wafer WA to cover the plurality of second interposer pads 35, and an exposure process and a development process may be performed on the first photoresist layer PR1 to form openings that expose the plurality of second interposer pads 35 respectively. Then, an electroplating process may be performed to form the first conductive layer 111 on each of the plurality of second interposer pads 35. Then, the first photoresist layer PR1 may be removed from the wafer WA.

Referring to FIGS. 10 and 11, processes the same as or similar to the processes described with reference to FIGS. 6 to 9 may be performed to form a second conductive layer 112 on the first conductive layer 111. For example, the second conductive layer may include a metallic material such as copper (Cu), nickel (Ni), etc.

For example, a second photoresist layer PR2 may be formed on the second interposer insulation layer 34 of the wafer WA to cover the first conductive layer 111, and an exposure process and a development process may be performed on the second photoresist layer PR2 to form openings that expose the first conductive layers 111 respectively. Then, an electroplating process may be performed to form the second conductive layer 112 on the first conductive layer 111. Then, the second photoresist layer PR2 may be removed from the wafer WA.

Referring to FIGS. 12 and 13, processes the same as or similar to the processes described with reference to FIGS. 6 to 9 may be performed to form a third conductive layer 113 on the second conductive layer 112. For example, the third conductive layer may include a metallic material such as copper (Cu), nickel (Ni), etc.

For example, a third photoresist layer PR3 may be formed on the second interposer insulation layer 34 of the wafer WA to cover the second conductive layer 112, and an exposure process and a development process may be performed on the third photoresist layer PR3 to form opening that expose the second conductive layers 112 respectively. Then, an electroplating process may be performed to form the third conductive layer 113 on the second conductive layer 112. Then, the third photoresist layer PR3 may be removed from the wafer WA.

Referring to FIGS. 14 to 16, processes the same as or similar to the processes described with reference to FIGS. 6 to 9 may be performed to form a first bump solder 120 on the third conductive layer 113. For example, the first bump solder 120 may include a solder material such as tin (Sn). A first bump pillar 110 and the first bump solder 120 may then be heated to form a plurality of first conductive bumps 100 on the plurality of second interposer pads 35.

For example, a fourth photoresist layer PR4 may be formed on the second interposer insulation layer 34 of the wafer WA to cover the third conductive layer 113, and an exposure process and a development process may be performed on the fourth photoresist layer PR4 to form openings that expose the third conductive layers 113 respectively. Then, an electroplating process may be performed to form the first bump solder 120 on the third conductive layer 113. Then, the fourth photoresist layer PR4 may be removed from the wafer WA.

Then, the first bump pillar 110 and the first bump solder 120 including the first, second, and third conductive layers 111, 112 and 113 may be heated and cooled by a reflow process to form the plurality of first conductive bumps 100, each including the first, second and third conductive layers 111, 112, 113 and the first bump solder 120 are bonded together. For example, the first bump solder 120 of each of the plurality of first conductive bumps 100 may have a rounded shape due to the reflow process.

Referring to FIGS. 17 to 19, a molding material may be formed on the second interposer insulation layer 34 of the wafer WA to cover the plurality of first conductive bumps 100, and the molding material and the plurality of first conductive bumps 100 may be partially removed to complete a molding layer 200 and the plurality of first conductive bumps 100.

For example, the molding material may be injected onto the second interposer insulation layer 34 of the wafer WA, and the molding material may be heated to form the molding layer 200 that covers the plurality of first conductive bumps 100. For example, the molding material may include a thermosetting material that hardens when heat is applied. The molding material may include epoxy molding compounds (EMC).

Then, an upper surface LS2 of the molding layer 200 may be partially removed by a grinding process and a chemical mechanical polishing (CMP) process. Additionally, the first bump solder 120 of each of the plurality of first conductive bumps 100 may be at least partially removed by the grinding process and the chemical mechanical polishing (CMP) process.

For example, a height of the molding layer 200 may be the same as a height of each of the plurality of first conductive bumps 100. Each of the plurality of first conductive bumps 100 may have a first height H1, and the molding layer 200 may have a second height H2 equal to the first height H1. For example, the first height may be a distance in a vertical direction VD from the second surface 31b of the interposer substrate 31 to an upper surface BS2 of each of the plurality of first conductive bumps 100. The second height may be a distance in the vertical direction VD from the second surface 31b of the interposer substrate 31 to the upper surface LS2 of the molding layer 200. Thus, the upper surface BS2 of each of the plurality of first conductive bumps 100 and the upper surface LS2 of the molding layer 200 may be coplanar with each other.

Referring to FIGS. 20 to 22, a semiconductor chip 40 may be mounted on an interposer 30, and an underfill member 70 may be formed in a gap G between the semiconductor chip 40 and the interposer 30.

In some implementations, the semiconductor chip 40 may include a semiconductor substrate 41 having a first surface 41a and a second surface 41b opposite to the first surface 41a, a semiconductor insulation layer 42 provided on the first surface 41a of the semiconductor substrate 41, and a plurality of chip pads 43 provided in the semiconductor insulation layer 42 to be at least partially exposed from the semiconductor insulation layer 42. The semiconductor chip 40 may further include a plurality of second conductive bumps 45 provided on the plurality of chip pads 43 to be in contact with the interposer 30.

Each of the plurality of second conductive bumps 45 may include a second bump pillar BP and a second bump solder BC that are sequentially stacked on each of the plurality of chip pads 43 to be electrically connected to each other. For example, the second bump pillar may include copper (Cu), nickel (Ni), etc, and the second bump solder may include a solder material such as tin (Sn), etc.

The second bump pillar BP may include a plurality of conductive layers stacked sequentially on each chip pad to be electrically connected to each other. For example, the second bump pillar may include a fourth conductive layer CL1, a fifth conductive layer CL2, and a sixth conductive layer CL3 that are sequentially stacked on the chip pad.

For example, the semiconductor chip 40 may be mounted on the interposer 30 via the plurality of second conductive bumps 45 respectively provided between the plurality of chip pads 43 and the plurality of first conductive bumps 100 to form the gap G between the semiconductor chip 40 and the interposer 30. For example, the plurality of second conductive bumps 45 of the semiconductor chip 40 may be respectively in contact with the plurality of first conductive bumps 100, to thereby electrically connect the interposer 30 and the semiconductor chip 40. The underfill member 70 may then be injected into the gap G between the semiconductor chip 40 and the interposer 30 to cover the plurality of second conductive bumps 45. For example, the underfill member may be a structure to physically protect the plurality of second conductive bumps 45.

Referring to FIGS. 23 to 25, a molding member 80 may be formed on the interposer 30 to cover the semiconductor chip 40, and the adhesive layer AL and the carrier CA may be removed from the interposer 30 to expose the plurality of first interposer pads 33, and a plurality of conductive connection members 39 may be attached onto the plurality of first interposer pads 33 respectively, and the interposer 30 and the molding member 80 may be cut along the scribe lane region SL of the interposer 30 to complete a semiconductor device SD.

Referring to FIG. 26, a package substrate 20 having a mounting region MR may be provided, and the semiconductor device SD may be mounted on the mounting region MR of the package substrate 20 to complete a semiconductor package 10.

Accordingly, since the plurality of first conductive bumps 100 and the molding layer 200 of the semiconductor package 10 are partially removed together through the grinding process and the chemical mechanical polishing process, the plurality of first conductive bumps 100 and the molding layer 200 may have the same height as each other. Thus, an area of the mating (or bonding) surface of each of the plurality of first conductive bumps 100 may be increased and the tolerance for the height of each of the plurality of first conductive bumps 100 may be decreased, so a slip phenomenon may be prevented or reduced from occurring during the bonding process of the plurality of first conductive bumps 100 and the plurality of second conductive bumps 45. Further, the first conductive bumps 100 may prevent or reduce misalignment between the interposer 30 and the semiconductor chip 40, to thereby increase reliability and yield rates.

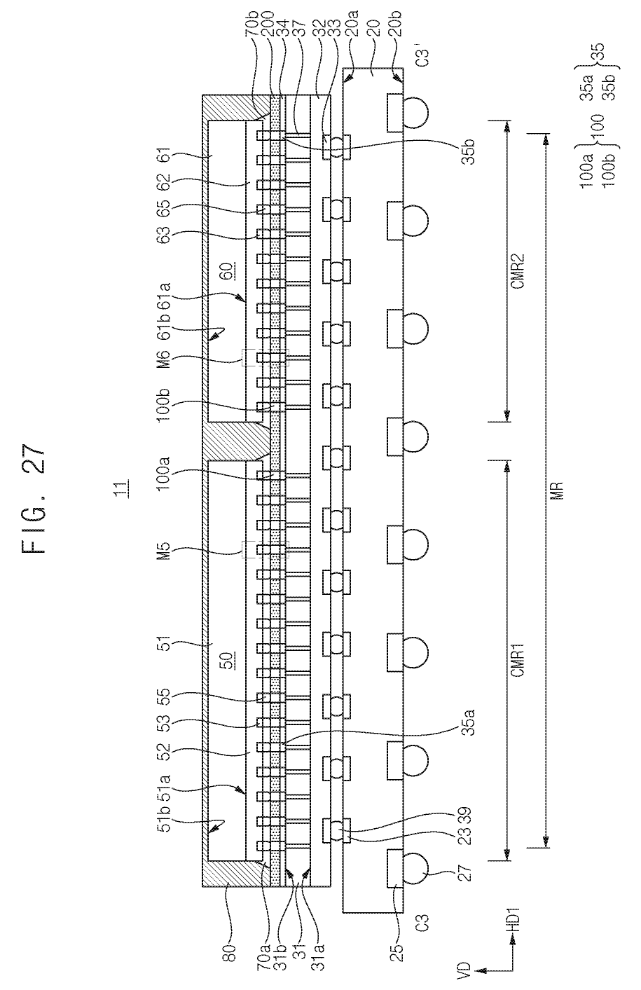

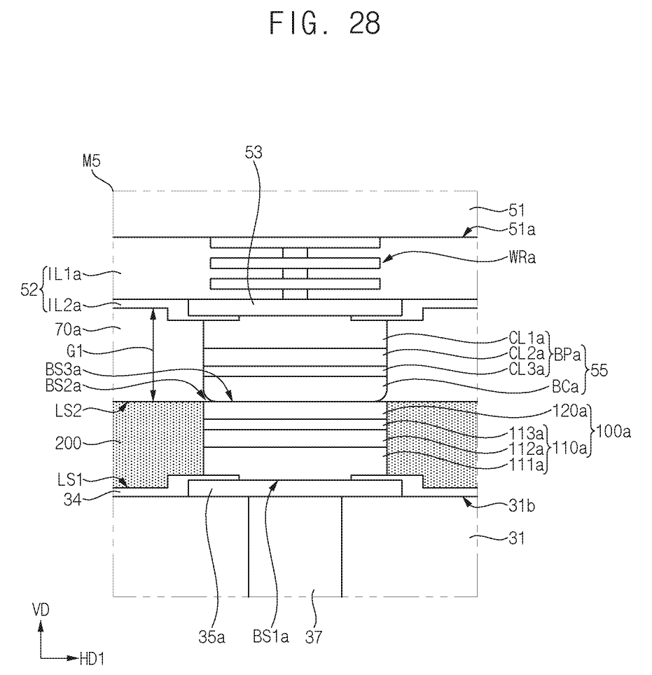

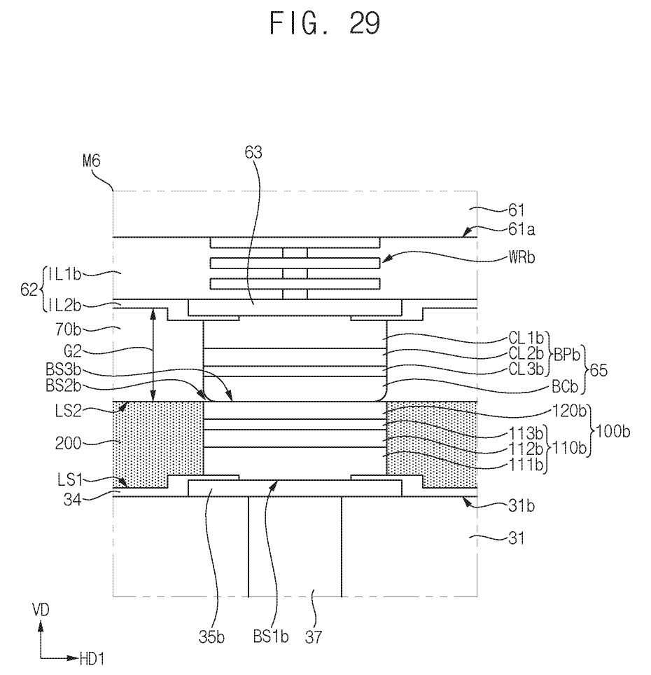

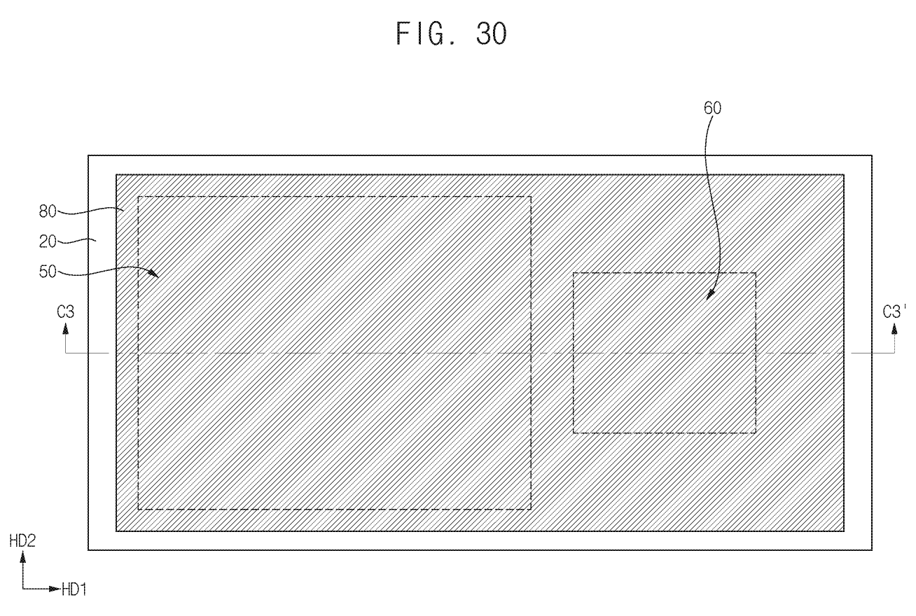

FIG. 27 is a cross-sectional view illustrating an example of a semiconductor package. FIG. 28 is an enlarged cross-sectional view illustrating portion ‘M5’ in FIG. 27. FIG. 29 is an enlarged cross-sectional view illustrating portion ‘M6’ in FIG. 27. FIG. 30 is a plan view illustrating the semiconductor package in FIG. 27. FIG. 27 is a cross-sectional view taken along the line C3-C3' in FIG. 30.

The semiconductor package illustrated in FIGS. 27 to 30 is substantially the same as or similar to the semiconductor package described with reference to FIGS. 1 to 3, except for a first semiconductor chip 50, a second semiconductor chip 60, third conductive bumps 100a, and fourth conductive bumps 100b, so that identical or similar components are denoted by the same reference numerals and repeated descriptions of identical or similar components are omitted.

Referring to FIGS. 27 to 30, a semiconductor package 11 may include a package substrate 20, an interposer 30 stacked on a mounting region MR of the package substrate 20, a first semiconductor chip 50 and a second semiconductor chip 60 stacked on the interposer 30, and a first underfill member 70a filling a first gap G1 between the interposer 30 and the first semiconductor chip 50, a second underfill member 70b that fills a second gap G2 between the interposer 30 and the second semiconductor chip 60, and a molding member 80 provided on the interposer 30 to cover the first semiconductor chip 50 and the second semiconductor chip 60.

For example, the first semiconductor chip 50 and the second semiconductor chip 60 may be a memory chip or a logic chip. As another example, the first semiconductor chip and the second semiconductor chip may be chiplets in which single semiconductor chips are mounted separately and together perform a single function.

The semiconductor package 10 may include a plurality of external connection members 27 provided on a lower portion of the package substrate 20 and a conductive connection member 39 provided between the package substrate 20 and the interposer 30.

The semiconductor package 10 may include a plurality of first conductive bumps 100 provided on an upper surface of the interposer 30 to be electrically connect the interposer 30 to the first semiconductor chip 50 and the second semiconductor chip 60, a plurality of third conductive bumps 55 provided below the first semiconductor chip 50 to electrically connect the interposer 30 and the first semiconductor chip 50, and a plurality of fourth conductive bumps 65 provided below the second semiconductor chip 60 to electrically connect the interposer 30 and the second semiconductor chip 60.

In some implementations, the interposer 30 may include an interposer substrate 31 having a first surface 31a and a second surface 31b opposite to the first surface 31a, a first interposer insulation layer 32 provided on the first surface 31a of the interposer substrate 31, and a plurality of first interposer pads 33 provided in the first interposer insulation layer 32 to be at least partially exposed from the first interposer insulation layer 32, a second interposer insulation layer 34 provided on the second surface 31b of the interposer substrate 31, and a plurality of second interposer pads 35 provided in the second interposer insulation layer 34 to be at least partially exposed from the second interposer insulation layer 34. The interposer 30 may further include a plurality of through vias 37 that are disposed within the interposer substrate 31 to electrically connect the plurality of first interposer pads 33 and the plurality of second interposer pads 35, and a plurality of conductive connection members 39 disposed on the plurality of first interposer pads 33 respectively.

The interposer 30 may include a plurality of first conductive bumps 100 respectively provided on the plurality of second interposer pads 35 and a molding layer 200 provided on the second interposer insulation layer 34 to at least partially expose the plurality of first conductive bumps 100.

The interposer 30 may include a first chip mounting region CMR1 and a second chip mounting region CM2 spaced apart from the first chip mounting region CMR1 in a first horizontal direction HD1. For example, the first chip mounting region and the second chip mounting region may be regions for mounting semiconductor chips to be described later.

The plurality of second interposer pads 35 of the interposer 30 may include a plurality of first pads 35a disposed within the first chip mounting region CMR1 and a plurality of second pads 35b disposed within the second chip mounting region CMR2.

The plurality of first conductive bumps 100 of the interposer 30 may include a plurality of first interposer bumps 100a respectively provided on the plurality of first pads 35a to be disposed within the first chip mounting region CMR1 and a plurality of second interposer bumps 100b respectively provided on the plurality of second pads 35b to be disposed within the second chip mounting region CMR2.

The plurality of first interposer bumps 100a and the plurality of second interposer bumps 100b may have substantially the same configuration as the plurality of first conductive bumps 100 described with reference to FIGS. 1 to 3. Accordingly, descriptions of the substantially identical or similar configurations are omitted.

A height of each of the plurality of first interposer bumps 100a and a height of each of plurality of second interposer bumps 100b may be the same as a height of the molding layer 200. For example, an upper surface BS2a of each of the plurality of first interposer bumps 100a and an upper surface BS2b of each of the plurality of second interposer bumps 100b may be coplanar with an upper surface LS2 of the molding layer 200.

In some implementations, the first semiconductor chip 50 may include a first semiconductor substrate 51 having a first surface 51a and a second surface 51b opposite to the first surface 51a, a first semiconductor insulation layer 52 provided on the first semiconductor substrate 51, and a plurality of first chip pads 53 provided in the first semiconductor insulation layer 52 to be at least partially exposed from the first semiconductor insulation layer 52. In addition, the first semiconductor chip 50 may further include a plurality of third conductive bumps 55 respectively provided on the plurality of first chip pads 53 to be in contact with the interposer 30.

The first semiconductor insulation layer 52 may be provided on the first surface 51a as an active surface of the first semiconductor substrate 51. The first semiconductor insulation layer 52 may include a plurality of first insulation layers IL1a and IL2a and a plurality of first wirings WRa in the first insulation layers. Further, a plurality of first chip pads 53 may be provided in the outermost insulation layer IL2a of the first semiconductor insulation layer 52.

The plurality of third conductive bumps 55 may have substantially the same configuration as the plurality of second conductive bumps 45 described with reference to FIGS. 1 to 3. Accordingly, descriptions of the substantially identical or similar configurations are omitted.

The first semiconductor chip 50 may be mounted on the first chip mounting region CMR1 of the interposer 30 via the plurality of third conductive bumps 55 that are provided between the plurality of first chip pads 53 and the plurality of first interposer bumps 100a to form a first gap G1 between the first semiconductor chip 50 and the interposer 30. For example, the plurality of third conductive bumps 55 of the first semiconductor chip 50 may respectively contact the plurality of first interposer bumps 100a to electrically connect the interposer 30 and the first semiconductor chip 50. For example, a lower surface BS3a of each of the plurality of third conductive bumps 55 may contact the upper surface BS2a of each of the plurality of first interposer bumps 100a.

In some implementations, the second semiconductor chip 60 may include a second semiconductor substrate 61 having a first surface 61a and a second surface 61b opposite to the first surface 61a, a second semiconductor insulation layer 62 provided on the second semiconductor substrate 61, and a plurality of second chip pads 63 provided in the second semiconductor insulation layer 62 to be at least partially exposed from the second semiconductor insulation layer 62. In addition, the second semiconductor chip 60 may further include a plurality of fourth conductive bumps 65 respectively provided on the plurality of second chip pads 63 to be in contact with the interposer 30.

The second semiconductor insulation layer 62 may be provided on the first surface 61a as an active surface of the second semiconductor substrate 61. The second semiconductor insulation layer 62 may include a plurality of second insulation layers IL1b and IL2b and a plurality of second wirings WRb within the first insulation layer. Further, a plurality of second chip pads 63 may be provided in the outermost insulation layer IL2b of the second semiconductor insulation layer 62.

The plurality of fourth conductive bumps 65 may have substantially the same configuration as the plurality of second conductive bumps 45 described with reference to FIGS. 1 to 3. Accordingly, descriptions of the substantially identical or similar configurations are omitted.

The second semiconductor chip 60 may be mounted on the second chip mounting region CMR2 of the interposer 30 via the plurality of fourth conductive bumps 65 that are respectively provided between the plurality of second chip pads 63 and the plurality of second interposer bumps 100b to form a second gap G2 between the second semiconductor chip 60 and the interposer 30. For example, the plurality of fourth conductive bumps 65 of the second semiconductor chip 60 may respectively contact the plurality of second interposer bumps 100b to electrically connect the interposer 30 and the second semiconductor chip 60. For example, a lower surface BS3b of each of the plurality of fourth conductive bumps 65 may be in contact with the upper surface BS2b of each of the plurality of second interposer bumps 100b.

As discussed above, the semiconductor package 11 may include the package substrate 20, the interposer 30 stacked on the package substrate 20, the first semiconductor chip 50 and the second semiconductor chip 60 stacked on the interposer 30, the first underfill member 70a provided between the interposer 30 and the first semiconductor chip 50, the second underfill member 70b provided between the interposer 30 and the second semiconductor chip 60, and the molding member 80 covering the first semiconductor chip 50 and the second semiconductor chip 60.

The interposer may include the first interposer bumps 100a provided within the first chip mounting region CMR1, the second interposer bumps 100b provided within the second chip mounting region CMR2, and the molding layer 200 at least partially exposing the first interposer bumps 100a and the second interposer bumps 100b.

The height of each of the first interposer bumps 100a and the height of each of the second interposer bumps 100b may be the same as the height of the molding layer 200.

The exposed surface BS2a of each of the first interposer bumps 100a and the exposed surface BS2b of each of the second interposer bumps 100b may be coplanar with each other, thereby increasing the bonding surface of the first interposer bumps 100a and the second interposer bumps 100b.

Further, in some implementations since the first interposer bumps 100a have the same heights, the tolerance on the heights of the first interposer bumps 100a may be reduced, and furthermore, a slip phenomenon between the first semiconductor chip 50 and the interposer 30 may be prevented. Similarly, since the second interposer bumps 100b have the same heights, the tolerance for the heights of the second interposer bumps 100b may be reduced, and furthermore, a slip phenomenon between the second semiconductor chip 60 and the interposer 30 may be prevented.

Thus, the first interposer bumps 100a and the second interposer bumps 100b may prevent or reduce misalignments, thereby increasing reliability and yield.

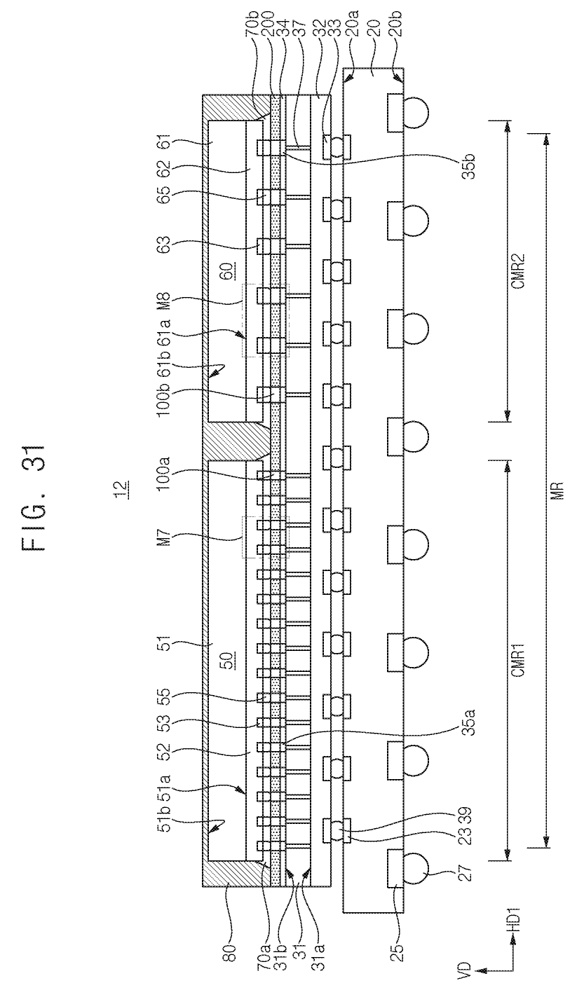

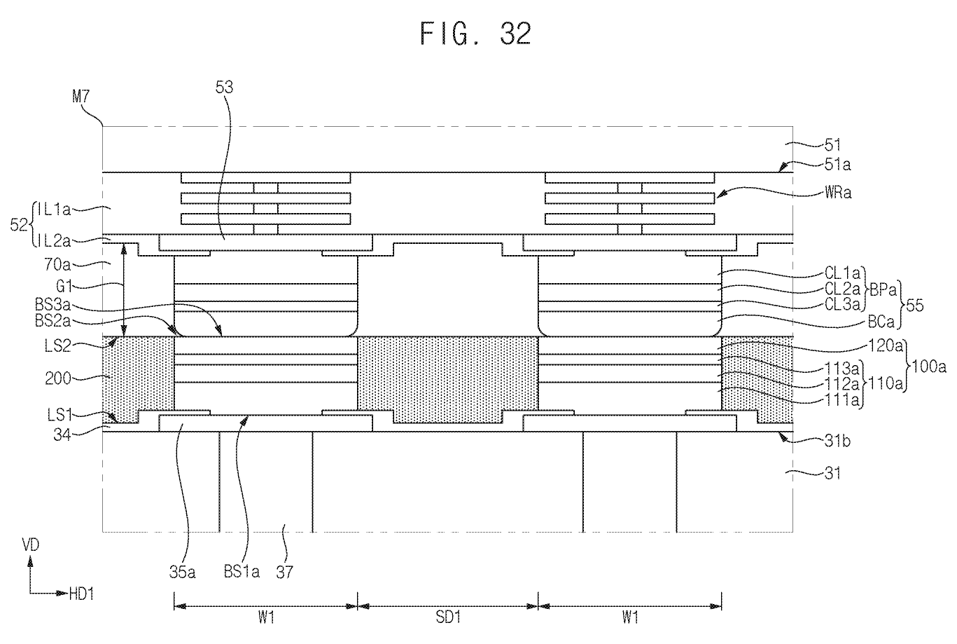

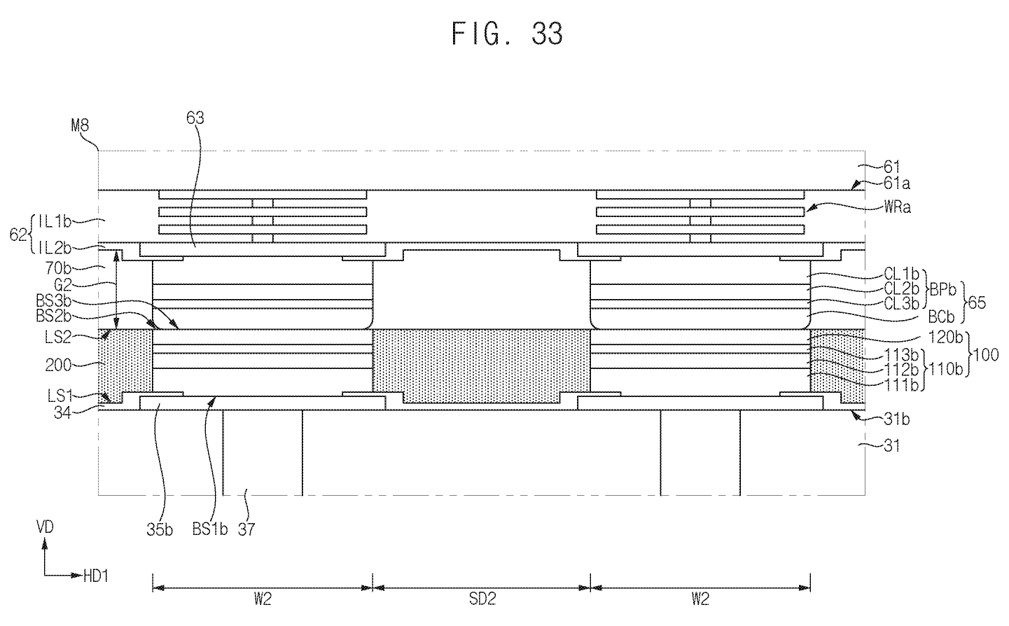

FIG. 31 is a cross-sectional view illustrating an example of a semiconductor package. FIG. 32 is an enlarged cross-sectional view illustrating portion ‘M7’ in FIG. 31. FIG. 33 is an enlarged cross-sectional view illustrating portion ‘M8’ in FIG. 31.

The semiconductor package illustrated in FIGS. 31 to 33 is substantially the same as or similar to the semiconductor package described with reference to FIGS. 27 to 30, except for diameters of each of the first interposer bumps 100a and the second interposer bumps 100b and spacing distances of the first interposer bumps 100a and second interposer bumps 100b, so identical or similar components are denoted by the same reference numerals, and repeated descriptions of identical or similar components are omitted.

Referring to FIGS. 31 to 33, a semiconductor package 12 may include a package substrate 20, an interposer 30 stacked on a mounting region MR of the package substrate 20, a first semiconductor chip 50 and a second semiconductor chip 60 stacked on the interposer 30, a first underfill member 70a filling a first gap G1 between the interposer 30 and the first semiconductor chip 50, a second underfill member 70b filling a second gap G2 between the interposer 30 and the second semiconductor chip 60, and a molding member 80 provided on the interposer 30 to cover the first semiconductor chip 50 and the second semiconductor chip 60.

For example, the first semiconductor chip 50 and the second semiconductor chip 60 may be a memory chip or a logic chip. As another example, the first semiconductor chip 50 and the second semiconductor chip 60 may be chiplets in which single semiconductor chips are separately mounted and together perform a single function.

In some implementations, the interposer 30 may include a plurality of first conductive bumps 100 respectively provided on a plurality of second interposer pads 35 and a molding layer 200 provided on the second interposer insulation layer 34 to at least partially expose the plurality of first conductive bumps 100. Further, the interposer 30 may include a first chip mounting region CMR1 and a second chip mounting region CM2 spaced apart from the first chip mounting region CMR1 in a first horizontal direction HD1. For example, the first chip mounting region CMR1 and the second chip mounting region CMR2 may be regions for mounting semiconductor chips to be described later.

The plurality of first conductive bumps 100 of the interposer 30 may include a plurality of first interposer bumps 100a provided on a plurality of first pads 35a to be disposed within the first chip mounting region CMR1 and a plurality of second interposer bumps 100b provided on a plurality of second pads 35b to be disposed within the second chip mounting region CMR2.

A first diameter W1 in the horizontal direction of each of the plurality of first interposer bumps 100a may be different from a second diameter W2 in the horizontal direction of each of the plurality of second interposer bumps 100b. For example, the first diameter W1 may be less than the second diameter W2. However, it will be appreciated that implementations are not limited thereto. Accordingly, the first diameter W1 may be greater than the second diameter W2.

A first spacing distance SD1 in the horizontal direction of the plurality of first interposer bumps 100a may be different from a second spacing distance SD2 in the horizontal direction of the plurality of second interposer bumps 100b. For example, the first spacing distance SD1 may be less than the second spacing distance SD2. However, it will be appreciated that implementations are not limited thereto. Accordingly, the first spacing distance SD1 may be greater than the second spacing distance SD2.

For example, the first diameter W1 in the horizontal direction of each of the plurality of first interposer bumps 100a and the first spacing distance SD1 in the horizontal direction of the plurality of first interposer bumps 100a may be determined according to the first semiconductor chip 50 mounted on the first chip mounting region CMR1. The first diameter may be determined in consideration of a diameter of each of the plurality of third conductive bumps 55. Further, the first spacing distance may be determined in consideration of a spacing distance of the plurality of third conductive bumps 55.

For example, the second diameter W2 in the horizontal direction of each of the plurality of second interposer bumps 100b and the second spacing distance SD2 in the horizontal direction of the plurality of second interposer bumps 100b may be determined according to the second semiconductor chip 60 mounted on the second chip mounting region CMR2. The second diameter may be determined in consideration a diameter of each of the plurality of fourth conductive bumps 65. Further, the second spacing distance may be determined in consideration of a spacing distance of the plurality of fourth conductive bumps 65.

As discussed above, the semiconductor package 12 may include the package substrate 20, the interposer 30 stacked on the package substrate 20, the first semiconductor chip 50 and the second semiconductor chip 60 stacked on the interposer 30, the first underfill member 70a provided between the interposer 30 and the first semiconductor chip 50, the second underfill member 70b provided between the interposer 30 and the second semiconductor chip 60, and the molding member 80 covering the first semiconductor chip 50 and the second semiconductor chip 60.

The interposer may include the first interposer bumps 100a provided within the first chip mounting region CMR1, the second interposer bumps 100b provided within the second chip mounting region CMR2, and the molding layer 200 at least partially exposing the first interposer bumps 100a and the second interposer bumps 100b.

The first diameter W1 of each of the first interposer bumps 100a may be different from the second diameter W2 of each of the second interposer bumps 100b. The first spacing distance SD1 of each of the first interposer bumps 100a may be different from the second spacing distance SD2 of each of the second interposer bumps 100b.

Accordingly, even when the third conductive bumps 55 of the first semiconductor chip 50 and the fourth conductive bumps 65 of the second semiconductor chip 60 have different diameters and different spacing distances, the first semiconductor chip 50 and the second semiconductor chip 60 may be mounted on the interposer. Furthermore, it may be possible to prevent or reduce misalignment from occurring due to a slip phenomenon between the first semiconductor chip 50 and the second semiconductor chip 60 and the interposer 30.

The semiconductor packages described herein may include semiconductor devices such as logic devices or memory devices. The semiconductor packages may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The foregoing is illustrative of various examples. Although these examples have been described, those skilled in the art will readily appreciate that many modifications are possible without materially departing from the scope of the present disclosure.

What is claimed is:

1. A semiconductor package, comprising:
an interposer comprising a plurality of first interposer pads on a surface of the interposer;
a plurality of first conductive bumps respectively on the plurality of first interposer pads;
a molding layer on the surface of the interposer, wherein the molding layer surrounds the plurality of first conductive bumps, and wherein an upper surface of each of the plurality of first conductive bumps is exposed by the molding layer;
a semiconductor chip comprising a plurality of chip pads on a surface of the semiconductor chip, wherein the semiconductor chip is on the molding layer with the surface of the semiconductor chip facing the interposer; and
a plurality of second conductive bumps respectively on the plurality of chip pads of the semiconductor chip, wherein each of the plurality of second conductive bumps comprises a lower surface in contact with the upper surface of a corresponding first conductive bump of the plurality of first conductive bumps,
wherein each of the plurality of first conductive bumps includes:
a first bump pillar on a corresponding first interposer pad of the plurality of first interposer pads, and
a first bump solder on the first bump pillar and exposed by the molding layer.

2. The semiconductor package of claim 1, wherein the molding layer comprises a surface through which the plurality of first conductive bumps are exposed, and
wherein the upper surface of each of the plurality of first conductive bumps is coplanar with the surface of the molding layer.

3. The semiconductor package of claim 1, wherein a first height from the surface of the interposer to the upper surface of each of the plurality of first conductive bumps is a same as a second height from the surface of the interposer to an upper surface of the molding layer.

4. The semiconductor package of claim 1, wherein each of the plurality of second conductive bumps includes:
a second bump pillar on a corresponding chip pad of the plurality of chip pads; and
a second bump solder on the second bump pillar.

5. The semiconductor package of claim 4, wherein the first bump pillar of each of the plurality of first conductive bumps includes a plurality of first conductive layers sequentially stacked on the corresponding first interposer pad, and
wherein the second bump pillar of each of the plurality of second conductive bumps includes a plurality of second conductive layers sequentially stacked on the corresponding chip pad.

6. The semiconductor package of claim 5, wherein the plurality of first conductive layers and the plurality of second conductive layers include at least one of copper or nickel.

7. The semiconductor package of claim 4, wherein the first bump solder and the second bump solder include a solder material configured to bond the plurality of first conductive bumps to the plurality of second conductive bumps.

8. The semiconductor package of claim 1, wherein a diameter of each of the plurality of first conductive bumps is a same as a diameter of each of the plurality of second conductive bumps.

9. The semiconductor package of claim 1, wherein a diameter of each of the plurality of first conductive bumps is different from a diameter of each of the plurality of second conductive bumps.

10. The semiconductor package of claim 9, wherein the diameter of each of the plurality of first conductive bumps is greater than the diameter of each of the plurality of second conductive bumps.

11. A semiconductor package, comprising:
a package substrate comprising a mounting region;
an interposer mounted on the mounting region of the package substrate, wherein the interposer includes:
a first chip mounting region and a chip second mounting region spaced apart from the first chip mounting region,
an interposer substrate comprising a surface,
a plurality of interposer pads on the surface of the interposer substrate,
a plurality of first conductive bumps respectively on the plurality of interposer pads, and
a molding layer on the surface of the interposer substrate, wherein the molding layer covers a side surface of each of the plurality of first conductive bumps;
a first semiconductor chip mounted on the first chip mounting region of the interposer; and
a second semiconductor chip mounted on the second chip mounting region of the interposer,
wherein each of the plurality of first conductive bumps includes:
a first bump pillar on a corresponding interposer pad of the plurality of interposer pads, and
a first bump solder on the first bump pillar, wherein the first bump solder is exposed by the molding layer, and
wherein a first height from the surface of the interposer substrate to an upper surface of each of the plurality of first conductive bumps is a same as a second height from the surface of the interposer substrate to an upper surface of the molding layer.

12. The semiconductor package of claim 11, wherein the plurality of first conductive bumps include:
a plurality of first interposer bumps within the first chip mounting region and electrically connected to the first semiconductor chip; and
a plurality of second interposer bumps within the second chip mounting region and electrically connected to the second semiconductor chip.

13. The semiconductor package of claim 12, wherein a diameter of each of the plurality of first interposer bumps is a same as a diameter of each of the plurality of second interposer bumps.

14. The semiconductor package of claim 12, wherein a diameter of each of the plurality of first interposer bumps is different from a diameter of each of the plurality of second interposer bumps.

15. The semiconductor package of claim 12, wherein a spacing distance between adjacent first interposer bumps of the plurality of first interposer bumps is a same as a spacing distance between adjacent second interposer bumps of the plurality of second interposer bumps.

16. The semiconductor package of claim 12, wherein a spacing distance between adjacent first interposer bumps of the plurality of first interposer bumps is different from a spacing distance between adjacent second interposer bumps of the plurality of second interposer bumps.

17. The semiconductor package of claim 11, wherein the first semiconductor chip includes:
a first semiconductor substrate,
a plurality of first chip pads on a surface of the first semiconductor substrate, and
a plurality of second conductive bumps on the plurality of first chip pads, wherein the first semiconductor chip is mounted on the first chip mounting region of the interposer such that a first set of the plurality of first conductive bumps is respectively in contact with the plurality of second conductive bumps, and
wherein the second semiconductor chip includes:
a second semiconductor substrate,
a plurality of second chip pads on a surface of the second semiconductor substrate, and
a plurality of third conductive bumps on the plurality of second chip pads, wherein the second semiconductor chip is mounted on the second chip mounting region of the interposer such that a second set of the plurality of first conductive bumps is respectively in contact with the plurality of third conductive bumps.

18. The semiconductor package of claim 17, further comprising:
a first underfill member filling a first gap between the first semiconductor chip and the interposer, wherein the first underfill member covers the plurality of second conductive bumps; and
a second underfill member filling a second gap between the second semiconductor chip and the interposer, wherein the second underfill member covers the plurality of third conductive bumps.

19. The semiconductor package of claim 11, further comprising:
a molding member on the surface of the interposer substrate, wherein the molding member covers the first semiconductor chip and the second semiconductor chip.

20. A semiconductor package, comprising:
a package substrate comprising a mounting region;
a semiconductor chip mounted on the mounting region of the package substrate; and
an interposer interposed between the package substrate and the semiconductor chip, wherein the interposer is configured to electrically connect the package substrate to the semiconductor chip,
wherein the interposer includes:
an interposer substrate comprising a first surface facing the package substrate and a second surface opposite to the first surface and facing the semiconductor chip,
a plurality of interposer pads on the second surface of the interposer substrate,
a plurality of conductive bumps respectively on the plurality of interposer pads, and
a molding layer on the second surface of the interposer substrate, wherein the molding layer exposes the plurality of conductive bumps,
wherein each of the plurality of conductive bumps includes:
a bump pillar on a corresponding interposer pad of the plurality of interposer pads, and
a bump solder on the bump pillar, wherein the bump solder is exposed by the molding layer, and
wherein an upper surface of the bump solder of each of the plurality of conductive bumps is coplanar with an upper surface of the molding layer.
